(19) United States
(12) Patent Application Publication
(10) Pub. No.: US 2006/0124061 A1
(43) Pub. Date: Jun. 15, 2006

(54) Molecule supply source for use in thin-film forming

(76) Inventors: Tateo Saito, Ibaraki-ken (JP); Osamu Kobayashi, Ibaraki-ken (JP)

Correspondence Address: FLYNN THIEL BOUTELL & TANIS, P.C., 2026 RAMBLING ROAD, KALAMAZOO, MI, 49008-1631, US

(21) Appl. No.: 11/205,734

(22) Filed: Aug. 17, 2005

(30) Foreign Application Priority Data
Dec. 13, 2004 (JP) JP2004-359650

(51) Int. Cl. C23C 16/00

(52) U.S. Cl. 118/726

(57) ABSTRACT

A molecule supply source for use in thin-film forming, enabling to form a thin-film, having a high uniformity, with molecules discharged from a single evaporation source, even on a relatively wide film-forming surface 9, has guide passages 4a, 4b and 4c, being provided in plural numbers thereof, wherein flow rates and directional properties of the vapor molecules are controlled by those guide passages 4a, 4b and 4c; thereby, improving distribution on film-thickness, which are formed on the film-forming surface 9 of a substrate 8. With this, a necessary amount of film-forming material can reach to necessary portions on the film-forming surface 9 of the substrate 8, and therefore, it is possible to reduce dispersion in the film-thickness of the thin-film formed on the film-forming surface 9, but without rotating and/or moving the film-forming surface 9, and thereby enabling to obtain the thin-film, having the uniform film-thickness. Further, it is also possible to control the film-thickness at an arbitrary portion on the film-forming surface 9, freely, but up to a certain degree.

### BACKGROUND OF THE INVENTION

The present invention relates to a molecule supply source for use in thin-film forming, for heating a material to be formed on a film-forming surface of a solid body or matter, such as, a substrate, etc., in the form of a thin-film, thereby melting and evaporating the film-forming material; i.e., generating evaporated molecules for growing up the thin-film upon the surface of the solid body, and it relates to, in particular, a molecule supply source for use in thin-film forming, being suitable for accumulating the thin-film upon a film-forming surface having a relatively large area of the solid body, with uniformity, when accumulating the thin-film upon the solid body, such as, the substrate, etc.

When producing semiconductor devices and/or display apparatuses, a process for forming a thin-film is very important technology, for forming various kinds o9f thin-films upon the film forming surfaces thereof. The thin-film of such kind is obtained or formed through heating up a film-forming material within a vacuum, so as to blasted onto the substrate, and then it is cooled down; thereby, to be solidified or bonded thereon. In general, there is applied a method of putting the film-forming material into a melting pot or a crucible, which is made of a material having high meting-point, such as, tungsten, etc., and then heating up the material to be formed into the thin-film through heating the periphery of the crucible by means of a heater; thereby, generating the vapor thereof to be blasted onto the substrate.

Accompanying the large-sizing of display apparatuses or devices in recent years, also a film-forming surface comes to be large in the area thereof, on which the thin-film is to be formed. Accompanying with this, there comes out a problem, in particular, in an aspect of forming the thin-film upon the film-forming surface, which has the relatively large area, with uniform film-thickness.

In general, when a molecule discharge opening of a molecular beam source is single in the number thereof, distribution on the film-thickness formed on the film-forming surface is in proportion to cos³α, where assuming an angle from an exit of an evaporation source is α. For the purpose of compensating this, conventionally, various manners or methods are applied. For example, as is described in Japanese Patent Laying-Open No. 2004-176111 (2004), for example, attempts are made for obtaining leveling in the film-thickness thereof, such as, by rotating or moving the film-forming surface during when forming a film thereon, etc.

However, with such the means, there is necessity of mechanisms of rotating and/or moving a substrate having the film-forming surface thereof, and therefore a film-forming apparatus itself comes to be complicated. In particular, in case when dealing with a substrate, which has the film-forming surface of a large area, such a rotating mechanism and/or a moving mechanism for the substrate comes to be a main factor or cause of brining the apparatus to be large-sized; therefore, actually, it is inapplicable.

For this reason, conventionally, a distance is taken to be long between the discharge position of molecules and the film-forming surface, so that the film forming is carried out only within an area or region where a relatively uniform film-thickness can be obtained. However, if making long the distance between the molecules discharge position and the film-forming surface, only a portion of molecules of the film-forming material accumulate upon the film-forming surface, but much larger percentage of molecules accumulate on an interior wall of the vacuum chamber without contributing to the film forming. Then, much of the film-forming material is consumed uselessly or wasted, and it lowers down a yield rate, and at the same time contaminates an inside of the vacuum chamber with the film-forming material. With a material of an organic luminescence film, upon which attentions are paid, particularly, in recent years, it is high in the material cost, then lowering of the yield rate brings about a serious cost-up of the thin-film elements.

Also, as other means of manner for obtaining a uniform film-thickness of a thin-film formed on the film-forming surface, as is described in Japanese Patent-Laying Open of International Patent Application No. 2003-522839 (2003), for example, there is proposed a means of disposing molecule discharge portions at plural numbers of positions, dispersedly, thereby discharging molecules of the film-forming material, respectively, while controlling them, from each of those molecule discharge portions.

However, with this means, locally, the film comes to be large in the film-thickness thereof, in particular, at a portion where the film-forming surface is opposite to the molecule discharge portion, basically.

Further, there is also applied a molecule supply apparatus, being provided with a guide passage for discharging molecules of the film-forming material from one crucible to positions corresponding to the corners of the film-forming surface. However, with such the molecule supply apparatus, it is necessary to dispose the molecule discharge openings of the guide passage on a surface, having same sizes to the film-forming surface of the substrate. For this reason, accompanying with large-sizing of the substrate, as well as, becoming complicate in the structure thereof, there is a drawback that also the structures of the sizes of the guide passages becomes large.

An object is, according to the present invention, being accomplished by taking the drawbacks of the conventional molecule supply source for use in thin-film forming into the consideration thereof, to provide a molecule supply source for use in thin-film forming, enabling to form the thin-film having a film-thickness being high in the uniformity thereof, by means of molecules emitted from a single evaporation source, even upon a relatively wide film-forming surface.

According to the present invention, guide passages 4a, 4b and 4c are provided in plural numbers thereof, directing to the film-forming surface 9 of the substrate 8, so as to control the flow rate and the directional property of the molecule vapor by means of the guide passages 4a, 4b and 4c, thereby improving distribution of the film-thickness formed on the film-forming surface 9 of the substrate 8. With this, since it is possible to let a necessary amount of the film-forming material to reach to necessary portions on the film-forming surface 9 of the substrate 8, therefore the dispersion can be made small in the film-thickness of the thin-film, which is formed on the film-forming surface 9, but without rotating and/or moving the film-forming surface 9; thereby enabling to form a thin-film having a uniform thickness. Further, it is possible to control the film-thickness at arbitrary portions on the film-forming surface 9, freely up to a certain degree.

Namely, within the molecule supply source for use in thin-film forming, according to the present invention, guide passages 4a, 4b and 4c are provided in plural numbers thereof, in radial manner, each having a cylindrical passage for discharging molecules from the evaporation source 1 directed to the film-forming surface 9, wherein regulation means are provided in either a part or all of the guide passages (4a), (4b) and (4c), for regulating areas of those passages.

With such the molecule supply source for use in thin-film forming, according to the present invention, because of provision of the plural numbers of guide passages 4a, 4b and 4c, each having the cylindrical passage, in the radial manner, the molecules discharged from those guide passages 4a, 4b and 4c have the directional properties; thereby enabling to supply the molecules onto positions targeted on the film-forming surface 9. And, the supply amount thereof can be controlled by means of the regulation means, which are provided in the guide passages 4a, 4b and 4c for regulating the passage areas thereof. With this, it is possible to supply an arbitrary amount of molecules onto arbitrary positions on the film-forming surface 9. Accordingly, with supplying the molecules much more onto the peripheral portions or the like on the film-forming surface 9 of the substrate 8, where the film-thickness can easily become thin, it is possible to obtain standardization or leveling in the film-thickness of the thin-film to be formed thereon. With this, it is possible to form a thin-film being uniform much more, in particular, in distribution of the film-thickness. Further, it is preferable that the positions where lines extended from central lines of the guide passages 4b and 4c directing outwards reach onto the film-forming surface 9 lie on an outermost portion of the film-forming surface 9 or an outside thereof.

Within such the molecule supply source for use in thin-film forming, according to the present invention, the following relationship is established between “Do” and “Di”: Do≧Di, where “Di” is an inner diameter of each of plural numbers of the guide passages 4a, 4b and 4c, at a vapor inlet side, and “Do” an inner diameter thereof at a vapor exit side. As the regulation means for regulating the passage areas of the plural numbers of guide passages 4b are applied orifice-like limiter plates 5, each having a molecule pass opening 6 and being provided in the guide passages, respectively. With this limit plate 5, the molecule pass areas of the respective guide passages 4a, 4b and 4c are adjusted to be large or small, and thereby controlling the supply amount of molecules. A position where said limiter plate 5 is located satisfies the following relationship: Lr≧2×Dn, where “Lr” is a distance from an exit of the guide passage 4b to the limiter plate 5 and “Dn” a diameter of the molecule pass opening 6 of the limiter plate 5.

In accordance with such the molecule supply source for use in thin-film forming, as was mentioned above, according to the present invention, it is possible to discharge molecules from the guide passages 4a, 4b and 4c, with the directional properties, towards the film-forming surface 9, and at the same time, it is also possible to regulate the discharge amount of molecules from the guide passages 4a, 4b and 4c, for each. With this, it is possible to adjust the discharge amount of molecules on both the positions where the film-thickness can easily come to be thin and also where the film-thickness can easily comes to be thick, on a relatively wide film-forming surface 9; thereby, enabling to form a thin-film having a further uniform film-thickness on such film-forming surface 9.

### BRIEF DESCRIPTION OF THE SEVERAL VIEWS OF THE DRAWING

Those and other objects, features and advantages of the present invention will become more readily apparent from the following detailed description when taken in conjunction with the accompanying drawings wherein:

FIG. 1 is a vertical cross-section view for showing the molecule supply apparatus for use of thin-film forming, according to an embodiment of the present invention;

FIG. 2 is a view, being cut along a line A-A with arrows in FIG. 1 mentioned above;

FIG. 3 is a vertical cross-section view for showing the molecule supply apparatus for use of thin-film forming, according to another embodiment of the present invention; and

FIG. 4 is a view, being cut along a line B-B with arrows in FIG. 3 mentioned above.

### DETAILED DESCRIPTION OF THE INVENTION

According to the present invention, guide passages 4a, 4b and 4c are provided in plural numbers thereof, in radial directions, each having a cylindrical passage for discharging molecules directing from an evaporation source 1 to a film-forming surface 9, wherein a regulation means is/are provided in either a part or all of the guide passages 4a, 4b and 4c, for the purpose of regulating an area of the molecule passage, thereby achieving the object mentioned above.

Hereinafter, embodiments according to the present invention will be fully explained by referring to the attached drawings.

### Embodiment 1

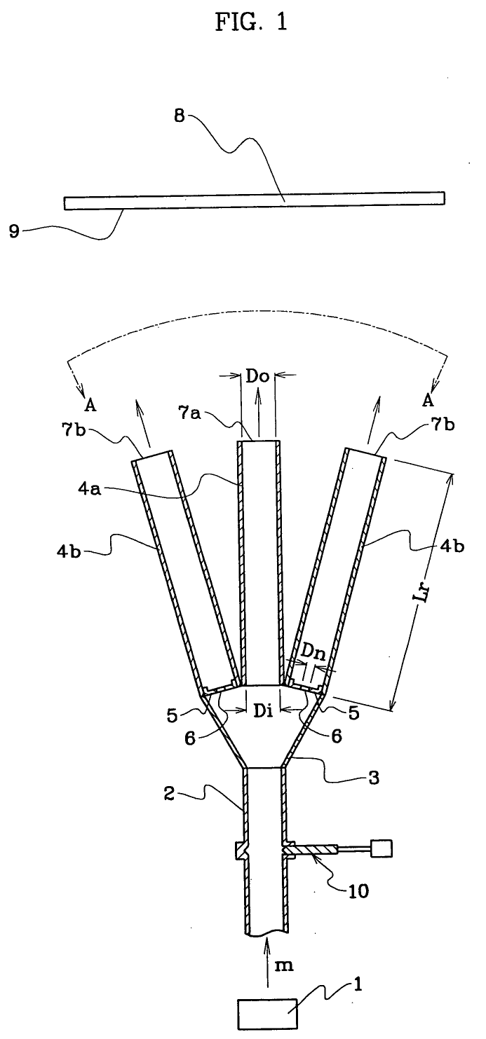

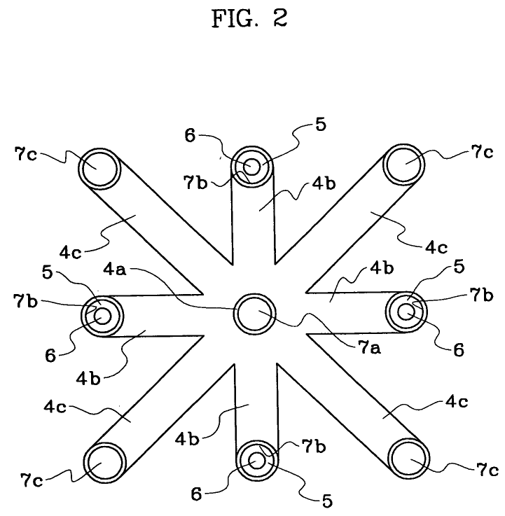

FIG. 1 is the vertical cross-section view of a molecule supply apparatus for use in thin-film forming, according to one embodiment of the present invention, and FIG. 2 is the view, being cut along a line A-A with arrows in FIG. 1.

As is shown in FIG. 1, molecules “m” supplied from a molecular beam source 1 are guided, through a duct 2, into a distributor chamber 3. On the way of the duct 2, there is provided a valve 10 for opening/closing a supply passage of molecules, thereby adjusting thereof.

To the distributor chamber 3 are connected guide passages 4a, 4b and 4c, each being cylindrical in the shape thereof, and those guide passages 4a, 4b and 4c are disposed in radial directions, directing to a film-forming surface 9 of a substrate 8. In more details thereof, a central guide passage 4a is disposed, so that it confronts a central portion of the film-forming surface 9 of the substrate 8, directing from the distributor chamber 3; however, other guide passages 4b and 4c, which are provided around, are disposed; i.e., each being opposite or facing to a portion near to a periphery of the film-forming surface 9, but being inclined a little bit, and also directing to an outside with respect to the central guide passage 4a mentioned above. The positions, where central axes of the peripheral guide passages 4b and 4c reach or come cross the film-forming surface 9 on the substrate 8, lie around the outermost positions of the film-forming surface 9 on the substrate 8.

Each of the guide passages 4a, 4b or 4c is a longitudinal and cylindrical molecule passage, but it may be in a square column shape in the place thereof, but as far as it has the passage therein. Those guide passages 4a, 4b and 4c have outlets 7a, 7b and 7c, each having a diameter “Do” being a little bit large, comparing to the diameter “Di” thereof on a side of the distributor chamber 3; i.e., Do≧Di.

Further, in an inlet of a part of the guide passages 4b, on the side of the distributor chamber 3, there is provided an orifice-like limiter plate 5 for limiting an area of that flow passage. In more details thereof, the limiter plate 5 is provided in four (4) pieces of the guide passages 4b, among eight (8) pieces of those guide passages 4b and 4c, which are surrounding the central guide passage 4a.

Each of those limiter plates 5 has a molecule pass opening 6 in the form of a hole, and the opening diameter “Dn” of this molecule pass opening 6 is smaller than the opening diameter “Di” of the guide passage 4a, 4b or 4c, which are provided on the side of the distributor chamber 3. Also, a length “Lr” of the molecule passage of the guide passage 4a, 4b or 4c is sufficiently long, comparing to the opening diameter “Dn” of the molecule pass opening 6 of the limiter plate 5; i.e., it is as two (2) times long as the opening diameter “Dn”, or longer than that. Namely, Lr≧2Dn.

Further, it is preferable in the structure, that the positions, where an each line, extending or prolonging outwards from a center line of the guide passage 4b or 4c reaches onto or comes cross the film-forming surface 9, lie on an outermost portion of the film-forming surface 9, or an outside thereof.

In this manner, since the length of the molecule passage of the guide passage 4a, 4b and 4c are long, then the molecule flows discharged from the outlets 7a, 7b and 7c are given with directional properties thereof, respectively, and therefore, molecules are discharged directing into a relatively narrow area or region at a predetermined position-on the film-forming surface 9 of the substrate 8. With this,even on a relatively wide film-forming surface 9, it is possible to keep the supply of an amount of molecules, being equal to that of the central portion, even on a peripheral portion where the film formed can be easily thinned; thereby, improving the uniformity of the film-thickness over the entire film-forming surface 9.

Within the vacuum, gaseous molecules go straight ahead. In case when introducing isotropic scattering molecules into the finite cylinder-like guide passages 4a, 4b and 4c, the directions of molecules discharged from the outlets 7a, 7b and 7c are determined due to the law of probability, i.e., depending upon the diameter of the guide passage 4a, 4b and 4c and the length of the guide passage 4a, 4b and 4c. The larger the ratio between the diameter and the length of the guide passage 4a, 4b and 4c, the wider the molecules are expanded, on the other hand, when the ratio comes down to be small, a percentage increases of the molecules advancing along the extended lines of the guide passages 4a, 4b and 4c. When using only one (1) piece of the guide passage, so as to emit molecules from this guide passage, then it is possible to have a vapor spouting in a manner of a cone, around the guide passage.

With provision of such the guide passages in plural numbers thereof while adjusting manners of overlapping the respective cones thereof, it is possible to improve distribution on the film-thickness formed on the film-forming surface of the substrate 8. In this instance, it is effective to dispose those guide passages 4a, 4b and 4c, mainly directing into a periphery side of the film-forming surface 9 on the substrate 8, while disposing the guide passage 4a directing to a middle portion thereof, where the film-thickness comes to be thin, in an auxiliary manner.

In this case, the necessary amount of molecules to be guided to those main guide passages 4b and 4c, which are disposed directing to the periphery portion of the film-forming surface 9, and that to the auxiliary guide passage 4a, which is disposed directing to the central portion of the film-forming surface 9, they are different from each other, depending upon a kind, temperature, and flow rate thereof, etc.; therefore, there is a necessity of providing a means for adjusting the molecule passages, respectively. In case of ssuming that the amount of molecules necessary for the guide passages 4b and 4c is 1, which are directed to the periphery portion of the film-forming surface 9, and also assuming that the amount of molecules necessary for the auxiliary guide passage 4a is 0.5, for example, then the total area of the molecule passages of those main guide passages 4b and 4c should be determined to be 1 while setting the molecule passage of the auxiliary guide passage 4a to be 0.5.

Also in case of providing the orifice-like limiter plate 5 in an inlet of the guide passages 4b, each, it is sufficient to determine the total area of the molecule passages of those main guide passages 4b, which are directed to the peripheral portion of the film-forming surface 9, in the similar manner; i.e., to be 1, while setting the molecule passage of the auxiliary guide passage 4a to be 0.5.

Although directions of the molecules discharged from the guide passages 4a, 4b and 4c are determined by the ratio between the diameter and the length of the guiding passages; however, in a case where the limiter plate 5 is provided, the molecule vapor is dispersed within the molecule pass opening 6 of the limiter plate 5. Therefore, the directional property of the molecule discharge depends upon the ratio, in particular, of the length “Lr” from the molecule pass opening 6 of the limiter plate 5 to an exit 7b of the guide passage 4b. Upon basis of the studies made by the inventors, for the purpose of regulating an extent of the vapor, effectively, it is preferable to determine the “Lr” to be equal or less than 2 times of “Dn”; i.e., Lr≧2Dn, but the effect cannot be obtained if “Lr” is less than that.

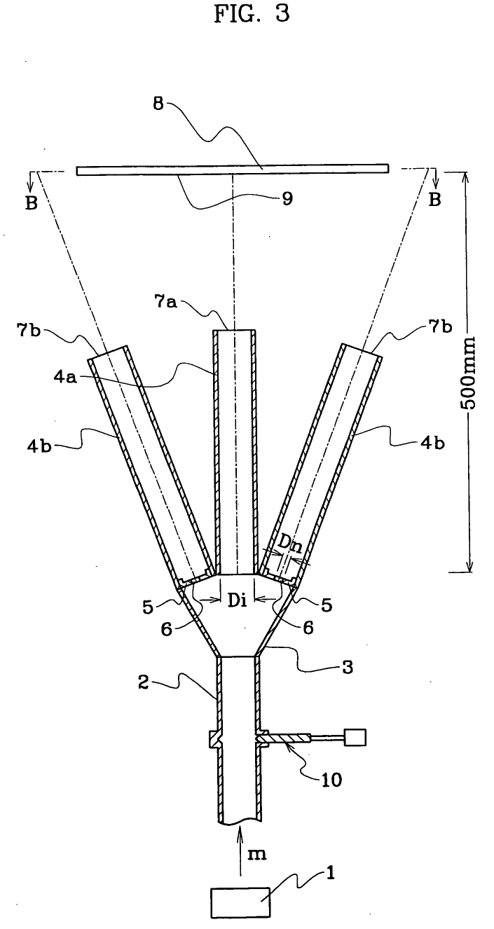

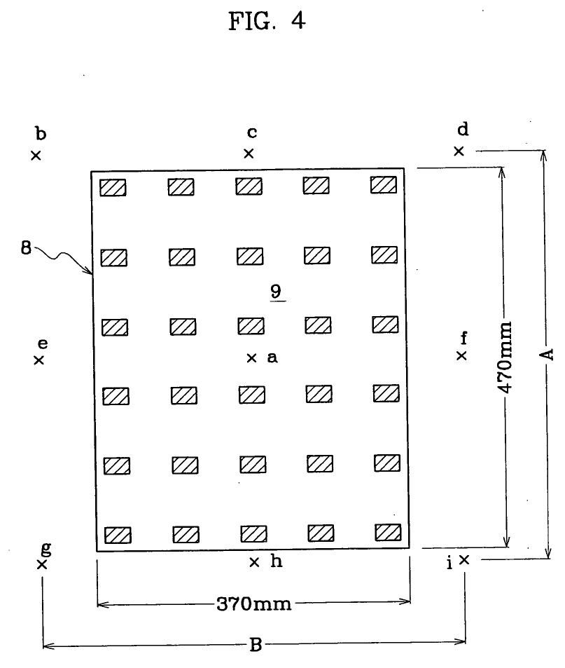

FIGS. 3 and 4 show an example of relationships established between the direction of the guide passages 4a, 4b and 4c and the positions of the film-forming surface 9. In this example, for the substrate having a height 470 mm, a width 370 mm, nine (9) pieces of guide passages 4a, 4b and 4c are positioned. The positions are indicated by marks “X” on FIG. 4, where the respective centerlines of those guide passages 4a, 4b and 4c reach onto or come across the surface, being same to the film-forming surface of the substrate 8. As is apparent from this FIG. 4, the central axis of the center guide passage 4a reaches to a center of the film-forming surface 9 on the substrate 8, as is indicated by a mark “a”. On the other hand, the central axes of the guide passages 4b and 4c around the center guide passage 4a, as indicated by marks “b” to “i”, reach to the corners of a square A (mm)×B (mm) surrounding the film-forming surface 9 of the substrate 8, and also the central positions on the respective sides of that square, upon the surface being same to the film-forming surface 9 on the substrate 8. The positions where the central axes of those guide passages 4b and 4c reach onto the surface, being same to the film-forming surface 9 of the substrate 8, are indicated by the marks “b” to “i”, and they are in an outside of the outermost position of the film-forming surface 9 of the substrate 8. In more details, it is preferable to determine A=B=500 mm, in particular, in the case of the substrate having such the sizes as was mentioned above.

Table 1 shows the minimum value and the maximum value of the film-thickness, as well as, a dispersion “δ” thereof, when actually forming the thin-film on the film-forming surface 9 of the substrate 8, while applying the molecule supply apparatus shown in FIGS. 3 and 4, therein. Each diameter of the guide passages 4a, 4b and 4c is 16φ, the sizes of the substrate 8 are, 370 mm×470 mm, and the distance is 500 mm from the molecular inlets of the guide passages 4a, 4b and 4c to the film-forming surface 9 of the substrate 8, for example. Also, the positions where the central axes of those guide passages 4b and 4c reach onto the surface, being the same to the film-forming surface 9 of the substrate 8, are as was mentioned in the above. Herein, a material of the organic luminescence film is used to be the film-forming material, such as, Alq 3, to be applied in the luminescence elements.

As a method for measuring the film-thickness, after sticking up thirty (3) pieces of measuring plates on the film-forming surface 9 of the substrate 8, measurement is made on the film-thickness thereof by a level detector (for example, “dektak 6”). The deviation “δ” between the maximum film-thickness (Tmax) and the minimum film-thickness (Tmin) can be expressed by an equation, i.e., 100×(Tmax—Tmin)/(Tmax+Tmin). The positions are indicated in FIG. 4 with square portions, which are treated with hatching thereon. A target value of the deviation “δ” in the film-thickness is determined to be δ≦5, and that having the deviation δ>6 is evaluated to be “x”.

TABLE 1

| | | Max. Value/ | | |
|---|---|---|---|---|
| Sample No. | δ | Min. Value | Evaluation | Notes |
| 1 | 45.4 | 0.375 | X | Comparison |
| 2 | 14.4 | 0.749 | X | Comparison |
| 3-1 | 3.1 | 1 | ⊚ | Embodiment |
| 3-2 | 3.7 | 0.928 | ⊚ | Embodiment |
| 4-1 | 5.9 | 0.889 | ◯ | Embodiment |
| 4-2 | 6.9 | 0.871 | X | Comparison |
| 5-1 | 24.1 | 0.612 | X | Comparison |
| 5-2 | 5.3 | 1 | ◯ | Embodiment |

Among those shown in the Table 1, the sample No. 1 is a case of discharging the molecules, directing to the center of the film-forming surface 9 of the substrate 8, but by means of only one (1) piece of the guide passage 4a. The sample No. 2 is of a case of supplying the molecules, uniformly, but without provision of the limiter plate 5, for all of nine (9) pieces of the guide passages 4a, 4b and 4c. The samples No. 3-1 through 5-1 are of the cases when forming the film with adjustment on the molecule passage areas of the guide passages 4a, 4b and 4c. In particular, the sample No. 3-1 shows a case of making adjustment with using the limiter plate, and the sample No. 3-2 shows a case of making adjustment on the diameter of the tube of the guide passage. The sample No. 4-1 shows a case when setting the positions “x” intersecting with the film-forming surface at the centers of the guide passages shown in FIG. 4, to be A=500 and B=500, respectively, and the sample No. 4-2 shows a case when setting, A=400 and B=400. Other than those, they are, A=500 and B=500. The sample No. 5-1 shows a case when providing the limiter plate at the molecule exit of each of the guide passages, and the sample No. 5-2 shows a case when providing the limiter plate at the position of 32 mm on a side of the molecular beam, from the molecule exit of each of the guide passages. The areas of molecule passages in those cases are shown in Table 2.

TABLE 2

| | | | |
|---|---|---|---|
| Sample No. 3-1 | b: 16 | c: 6.4 | d: 16 |
| | e: 6.4 | a: 0 | f: 6.4 |
| | g: 16 | h: 6.4 | i: 16 |
| Sample No. 3-2 | b: 16 | c: 6 | d: 16 |
| | e: 6 | a: 0 | f: 6 |
| | g: 16 | h: 6 | I: 16 |
| Sample No. 4-1 | b: 16 | C: 0 | d: 16 |
| | e: 5.6 | a: 0 | f: 5.6 |
| | g: 16 | h: 0 | i: 16 |
| Sample No. 4-2 | b: 16 | c: 0 | d: 16 |
| | e: 0 | a: 0 | f: 0 |
| | g: 16 | h: 0 | i: 16 |
| Sample No. 5-1 | b: 16 | C: 0 | d: 16 |
| | e: 0 | a: 0 | f: 0 |
| | g: 16 | h: 0 | i: 16 |
| Sample No. 5-2 | b: 16 | C: 0 | d: 16 |
| | e: 0 | a: 0 | f: 0 |
| | g: 16 | h: 0 | i: 16 |

The present invention may be embodied in other specific forms without departing from the spirit or essential feature or characteristics thereof. The present embodiment(s) is/are therefore to be considered in all respects as illustrative and not restrictive, the scope of the invention being indicated by the appended claims rather than by the forgoing description and range of equivalency of the claims are therefore to be embraces therein.

What is claimed is:

1. A molecule supply source for use in thin-film forming, for discharging molecules of a film-forming material generated towards a film-forming surface (9), to be adhered on the film-forming surface, thereby forming a film, comprising:
an evaporation source (1);
plural numbers of guide passages (4a), (4b) and (4c), each having a cylindrical passage for discharging the molecules directing from said evaporation source to the film-forming surface (9), being provided in radial manner; and
regulation means, being provided in either a part or all of said guide passages (4a), (4b) and (4c), for regulating an area(s) of molecule passage area(s) thereof.

2. The molecule supply source for use in thin-film forming, as described in the claim 1, wherein the following relationship is established between “Do” and “Di”:
Do≧Di
where “Di” is an inner diameter of each of plural numbers of said guide passages (4a), (4b) and (4c), at a vapor inlet side, and “Do” an inner diameter thereof at a vapor exit side.

3. The molecule supply source for use in thin-film forming, as described in the claim 1, wherein each of said regulation means for regulating the areas of the plural numbers of molecule passages (4b) is obtained through regulating an area of an inlet of each of said guide passages (4b).

4. The molecule supply source for use in thin-film forming, as described in the claim 2, wherein each of said regulation means for regulating the areas of the plural numbers of molecule passages (4b) is obtained through regulating an area of an inlet of each of said guide passages (4b).

5. The molecule supply source for use in thin-film forming, as described in the claim 1, wherein each of said regulation means for regulating the areas of the plural numbers of molecule passages (4b) has a molecule pass opening (6), respectively, and is constructed with an orifice-like limiter plate (5) provided in each of said guide passages (4b).

6. The molecule supply source for use in thin-film forming, as described in the claim 2, wherein each of said regulation means for regulating the areas of the plural numbers of molecule passages (4b) has a molecule pass opening (6), respectively, and is constructed with an orifice-like limiter plate (5) provided in each of said guide passages (4b).

7. The molecule supply source for use in thin-film forming, as described in the claim 3, wherein each of said regulation means for regulating the areas of the plural numbers of molecule passages (4b) has a molecule pass opening (6), respectively, and is constructed with an orifice-like limiter plate (5) provided in each of said guide passages (4b).

8. The molecule supply source for use in thin-film forming, as described in the claim 4, wherein each of said regulation means for regulating the areas of the plural numbers of molecule passages (4b) has a molecule pass opening (6), respectively, and is constructed with an orifice-like limiter plate (5) provided in each of said guide passages (4b).

9. The molecule supply source for use in thin-film forming, as described in the claim 8, wherein a position where said limiter plate (5) is located satisfies the following relationship:
Lr≧2×Dn
where “Lr” is a distance from an exit of said guide passage (4b) to said limiter plate (5) and “Dn” a diameter of the molecule pass opening (6) of said limiter plate (5).

10. The molecule supply source for use in thin-film forming, s described in the claim 1, wherein positions where lines extended from central lines of said guide passages (4b) and (4c) directing outwards reach onto said film-forming surface (9) lie on an outermost portion of said film-forming surface (9) or an outside thereof.

11. The molecule supply source for use in thin-film forming, as described in the claim 2, wherein positions where lines extended from central lines of said guide passages (4b) and (4c) directing outwards reach onto said film-forming surface (9) lie on an outermost portion of said film-forming surface (9) or an outside thereof.

12. The molecule supply source for use in thin-film forming, as described in the claim 3, wherein positions where lines extended from central lines of said guide passages (4b) and (4c) directing outwards reach onto said film-forming surface (9) lie on an outermost portion of said film-forming surface (9) or an outside thereof.

13. The molecule supply source for use in thin-film forming, as described in the claim 4, wherein positions where lines extended from central lines of said guide passages (4b) and (4c) directing outwards reach onto said film-forming surface (9) lie on an outermost portion of said film-forming surface (9) or an outside thereof.

14. The molecule supply source for use in thin-film forming, as described in the claim 5 wherein positions where lines extended from central lines of said guide passages (4b) and (4c) directing outwards reach onto said film-forming surface (9) lie on an outermost portion of said film-forming surface (9) or an outside thereof.

15. The molecule supply source for use in thin-film forming, as described in the claim 6, wherein positions where lines extended from central lines of said guide passages (4b) and (4c) directing outwards reach onto said film-forming surface (9) lie on an outermost portion of said film-forming surface (9) or an outside thereof.

16. The molecule supply source for use in thin-film forming, as described in the claim 7, wherein positions where lines extended from central lines of said guide passages (4b) and (4c) directing outwards reach onto said film-forming surface (9) lie on an outermost portion of said film-forming surface (9) or an outside thereof.

17. The molecule supply source for use in thin-film forming, as described in the claim 8, wherein positions where lines extended from central lines of said guide passages (4b) and (4c) directing outwards reach onto said film-forming surface (9) lie on an outermost portion of said film-forming surface (9) or an outside thereof.

18. The molecule supply source for use in thin-film forming, as described in the claim 9, wherein positions where lines extended from central lines of said guide passages (4b) and (4c) directing outwards reach onto said film-forming surface (9) lie on an outermost portion of said film-forming surface (9) or an outside thereof.
